(19) United States
(12) Patent Application Publication
(10) Pub. No.: US 2005/0212058 A1
(43) Pub. Date: Sep. 29, 2005

(54) Resistance-reduced semiconductor device and fabrication thereof

(76) Inventors: Yi-Chun Huang, Taoyuan (TW); Jyu-Horng Shieh, Hsinchu (TW); Ju-Wang Hsu, Taipei (TW)

Correspondence Address: BIRCH STEWART KOLASCH & BIRCH, PO BOX 747, FALLS CHURCH, VA, 22040-0747, US

(21) Appl. No.: 10/806,217

(22) Filed: Mar. 23, 2004

(51) Int. Cl. H01L 29/76; H01L 31/062

(52) U.S. Cl. 257/384; 257/388; 257/412

(57) ABSTRACT

A resistance-reduced semiconductor device and fabrication thereof. The semiconductor device of the invention includes a semiconductor device body exposing at least one silicon-containing portion, a metal silicide layer with a first resistivity overlying the silicon-containing portion and a conductor layer with a second resistivity overlying the metal silicide layer, wherein the second resistivity is smaller than the first resistivity.

### BACKGROUND

The present invention relates to semiconductor fabrication technology and in particular to a resistance-reduced semiconductor device fabricated by a self-aligned metallized (SAM) process.

Along with high integration, high performance, and low power consumption in semiconductor devices, a low resistance gate material is required to reduce a gate length in transistors and memory cells through formation of fine patterns and to improve device characteristics. The thickness of a gate insulating layer gradually decreases to increase a channel current in a transistor and a memory cell due to low power consumption. In order to prevent short channel effects caused by the reduction of the gate length in a transistor and secure a margin against punchthrough, the sacrificial resistance, for example, sheet resistance and contact resistance of a source/drain region, must be reduced when forming a shallow source/drain.

Therefore, integrated circuits (ICs) fabrication have been fabricated by a salicide (self-aligned silicide) process in which a silicide is formed on the surfaces of a gate and a source/drain region to thereby reduce the resistivity of the gate and the sheet resistance and contact resistance of the source/drain region. The salicide process indicates selective formation of a silicide region only on a gate and a source/drain region. The silicide region is formed of titanium silicide (TiSi₂) or materials of the group-VIII silicides (e.g., PtSi₂, PdSi₂, CoSi₂, and NiSi₂).

Nevertheless, process issues such as agglomeration or bubbles formed along a polysilicon or silicon boundary of a device does exist in the metal silicide layer having lowered sheet resistance formed by the conventional salicide process through reacting refractory metal with the silicon, and dislocation and discontinuity of boundary structures can be found therein due to poor thermal stability under high annealing temperature. Thus, an issue such as electrical disconnection or increased sheet resistance caused by the agglomeration of the metal silicide occurs and degrades reliability of the semiconductor device.

In U.S. Pat. No. 6,392,302, Hu discloses a polycide structure for use in an integrated circuit comprising a silicon layer, a barrier comprising ZWix where x is greater than two and Z is chosen from the group consisting of tungsten, tantalum and molybdenum and a metal silicide layer, preferably cobalt silicide. The barrier layer is formed prior to the formation of the metal silicide layer and the structure provides thermal stability, thus preventing agglomeration problems associated with a high temperature process combined with low resistivity.

Nevertheless, the metal silicide layer has poor resistance to the subsequent etching process such as plasma etching and can be partially removed thereby, thus degrading reliability of the device.

Hence, there is a need for a better resistance-reduced structure to prevent possible degradation of the metal silicide layer thereof.

### SUMMARY

Accordingly, an object of the invention is to provide a semiconductor device with resistance-reduced active regions to enhance device performance thereof.

In order to achieve the above object, the present invention provides a semiconductor device comprising a semiconductor device body exposing at least one silicon-containing portion, a metal silicide layer with a first resistivity overlying the silicon portion and a conductor layer with a second resistivity overlying the metal silicide layer, wherein the second resistivity is smaller than the first resistivity.

The present invention additionally provides a resistance-reduced transistor comprising a silicon substrate having a gate stack formed thereon, wherein the gate stack exposes a silicon gate electrode, a pair of source/drain regions oppositely disposed in the silicon substrate adjacent the gate stack and a metallized bilayer overlying each source/drain reigon and the silicon gate electrode thereby to respectively reduce resistance thereof, wherein the metallized bilayer comprises a metal top layer.

Another object of the invention is to provide a self-aligned metallization process for reducing resistance of an active region in a semiconductor device thus enhancing device performance thereof.

In order to achieve the above object, the present invention provides a method for fabricating a semiconductor device. First, a semiconductor device body exposing at least one silicon-containing portion is provided. Next, a metal silicide layer with a first resistivity is selectively formed over the silicon-containing portion and a conductor layer with a second resistivity is then formed on the metal silicide layer, wherein the second resistivity is smaller than the first resistivity.

In addition, the present invention further provides a method for fabricating a resistance-reduced transistor. First a silicon substrate having a gate stack formed thereon and a source/drain pair oppositely disposed in each side of the substrate adjacent to the gate stack is provided, wherein the gate stack comprises an exposed silicon gate electrode. Next, a metal silicide layer is selectively formed over the source/drain regions and the exposed silicon gate electrode. A metal layer is then selectively formed over each metal silicide layer to respectively reduce resistance of each source/drain region and the exposed silicon gate electrode.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1 to 5 are cross sections of a self-aligned metallizied process for fabricating a semiconductor device in one embodiment of the invention.

### DESCRIPTION

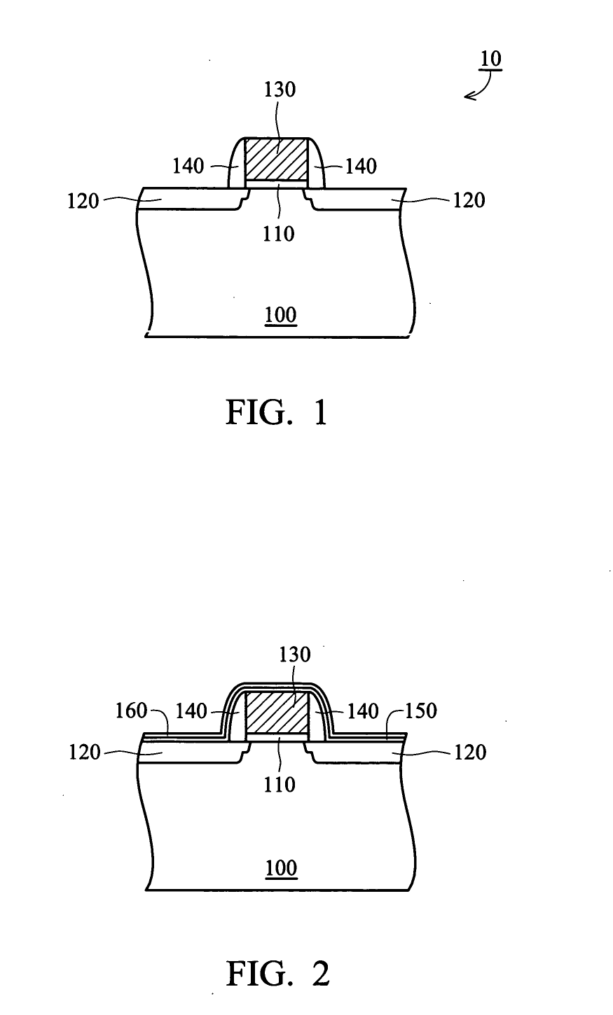

FIGS. 1 to 5 are cross sections showing a process for fabricating the resistance-reduced semiconductor device in accordance of one embodiment of the invention.

In FIG. 1, a silicon substrate 100 having a transistor 10 formed thereon is provided. Gate insulating layer 110 and gate electrode 130 of the transistor 10 are sequentially formed over a portion of the silicon substrate 100 to form a gate stack and the gate electrode 130 is insulated from the silicon substrate 100 by the gate insulating layer 110. In addition, a pair of source/drain regions 120 are oppositely disposed in the silicon substrate 100 adjacent to the gate electrode 130. Preferably, the gate electrode 130 is made of polysilicon and can be doped with impurities of proper conductive type, and the source/drain regions 120 are doped regions of N type or P type doping. Further, spacers 140 of insulating material are respectively formed on opposite sidewalls of the gate stack.

Next, the substrate 100 can be pre-cleaned by a cleaning solution such as diluted hydrofluoric (DHF) acid to remove the native oxide (not shown) formed thereon prior to the subsequent process steps.

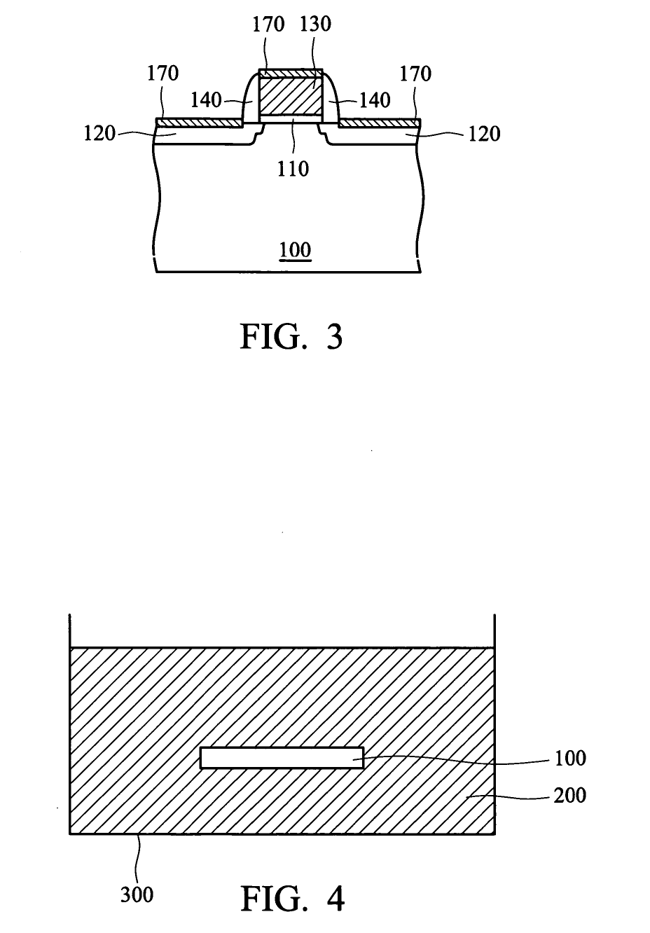

In FIG. 2, a metal layer 150 of about 30 Å to 400 Å is then blanketly formed over the silicon substrate 100 and covers the gate electrode 130, the spacers 140 and the source/drain regions 120. The method for forming the metal layer 150 can be physical vapor deposition (PVD), such as sputtering and material thereof can be Au or refractory metal such as cobalt (Co), tantalum (Ta), titanium (Ti), platinum (Pt), tungsten (W), nickel (Ni), palladium (Pd), etc.

A barrier 160 is then formed over the metal layer 150 to function as a diffusing barrier between the metal layer and the silicon substrate 100. The method for forming the barrier layer 160 can be, for example, chemical vapor deposition (CVD) and the material thereof can be such as titanium nitride, titanium or a composite layer thereof.

In FIG. 3, a thermal annealing process (not shown) is then performed at 250 to 750° C. to react the metal layer 150 with the silicon atoms in the silicon substrate 100 and the gate electrode 130, thus forming a silicide layer of the metal layer 150. Next, the portion of the metal layer 150 not reacted with the silicon substrate 100 and the gate electrode 130, and the barrier layer are removed through an etching method such as a wet etching. Thus, a metal silicide layer 170 with a first resistivity is thus formed over the gate electrode 130 and the source/drain regions 120 to respectively reduce the sheet resistance thereof. The metal silicide layer 170, however, has poor resistance to the subsequent etching such as plasma etching and undesirable effects such as agglomeration may occur thereon, thus degrading performance of transistor 10.

FIG. 4 illustrates a key feature of the invention, wherein the silicon substrate 100 having the transistor 10 partially covered by the metal silicide layer 170 is immersed into a chemical tank 300 containing an electrolyte 200. An electroless plating can thus be performed in the chemical tank 300 and a conductor layer 180 such as a metal layer can be thus selectively formed over each metal silicide layer 170 through ion reduction, without additional power supplied by an anode and a cathode, as it required in conventional electroplating.

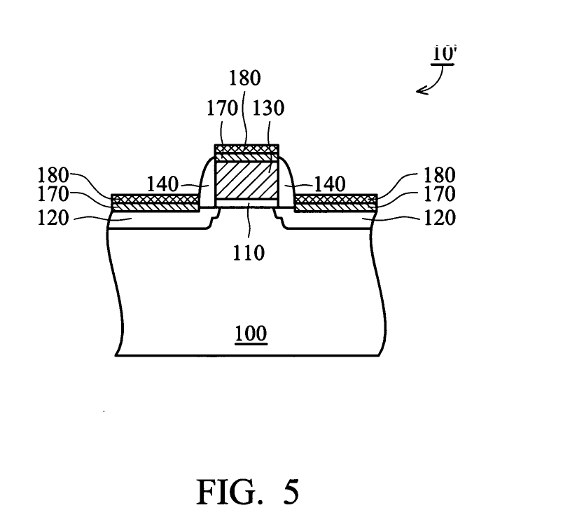

In FIG. 5, after the electroless plating, a conductor layer 180 with a second resistivity is respectively formed over each source/drain region 120 and the gate electrode 130, thus forming a self-aligned metallized bilayer thereon. As shown in FIG. 5, a resistance-reduced transistor 10′ of the invention comprises a silicon substrate 100 having a gate stack (referring to the gate electrode 130 and the gate insulator 110) formed thereon, wherein the gate stack exposes a silicon gate electrode thereof. A pair of source/drain regions 120 are oppositely disposed in the silicon substrate 100 adjacent the gate stack and a metallized bilayer (referring to the conductor layer 180 and the metal silicide layer 170) overlies each source/drain reigon and the silicon gate electrode thereby to respectively reduce resistance thereof, wherein the metallized bilayer comprises a metal top layer.

In the invention, the electrolyte 200 adopted in the electroless plating includes at least metal ions, catalysts such as palladium (Pd), Ni, Pt or Co, reducing agents such as sodium hypophosphite, formaldehyde, DEAB (n-diethylamine borane), sodium borohydride or hydrazine and complex agents such as EDTA, salts of tartaric acid or TEA (triethanolamine). Further, other agents such as stabilizer, buffer solution of predetermined metal ion, wetting agent or brightener can be further included in the electrolyte 200 to enhance the efficiency of the electroless plating. The metal ions in the electrolyte 200 can be ions of Au or refractory metal such as cobalt (Co), tantalum (Ta), titanium (Ti), platinum (Pt), tungsten (W), nickel (Ni), palladium (Pd), etc. Preferably, the metal salicide 170 is nickel silicide or cobalt silicide and the conductor layer 180 is a metal layer comprising the same metal ion as that of the metal silicide 170 thereunder.

Preferably, the metal ions in the electrolyte 200 are the same as those of the metal silicide layer 170, thus forming the conductor layer 180 from the same type of metal ion used in the metal silicide layer 170 thereunder for easy fabrication. The metal ions in the electrolyte 200 also function as a catalyst of the electrolyte 200 and thus enhance the electroless plating.

Moreover, the thickness of the conductor layer 180 is about 50 Å to 500 Å and has a thickness ratio of about 1:1-1:10 to the metal silicide layer 170. In the present invention, the metal silicide layer 170 also function as a seed layer When the thickness thereof is less then 50 Å. Due to the formation of the conductor layer 180 on the metal silicide layer 170, the metal material of the conductor layer 180 shows a second resistivity smaller than the first resistivity of the metal silicide layer 170, the sheet resistance over the gate electrode 130 and each source/drain region 120 can be lowered to a level of milliohms, thereby reducing contact resistance or sheet resistance of the device or active region thereof, thus enhancing performance thereof. Moreover, the metal material of the conductor layer 180 also shows a better etching resistance to the subsequent etching process for forming contact holes, for example, than the metal silicide layer 170 thereunder.

In the present invention, a self-aligned metallized (SAM) bilayer formed over a portion of a semiconductor device such as transistor to reduce sheet resistance or contact resistance thereon and the process for forming the same are illustrated. The metallized bilayer comprises a metal top layer and metal silicide bottom layer. The present invention is distinct from the bilayer polycide structure in U.S. Pat. No. 6,392,302 disclosed by Hu.

Moreover, the self-aligned metallization process of the invention is also applicable for forming a metallized bilayer over an exposed silicon portion of a semiconductor device such as a capacitor or a resistor to reduce the contact resistance therein. The exposed silicon portion described in the invention refers to a silicon-containing portion comprises doped or undoped monocrystal silicon, polysilicon, amorphous silicon or the like, and is not merely limited to the monocrystal silicon.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A semiconductor device, comprising:
a semiconductor device body exposing at least one silicon-containing portion;
a metal silicide layer with a first resistivity overlying the silicon-containing portion; and
a conductor layer with a second resistivity overlying the metal silicide layer, wherein the second resistivity is small than the first resistivity.

2. The semiconductor device as claimed in claim 1, wherein the conductor layer comprises the same type metal ion as that of the metal silicide layer.

3. The semiconductor device as claimed in claim 1, wherein the conductor layer comprises refractory metal.

4. The semiconductor device as claimed in claim 1, wherein the metal silicide layer comprises a silicide of refractory metal.

5. The semiconductor device as claimed in claim 1, wherein the conductor layer comprises a metal selected from a group consisting of Au, Pt, Ni, Co, Pd, W and Ti.

6. A resistance-reduced transistor, comprising:
a silicon substrate having a gate stack formed thereon, wherein the gate stack exposes a silicon gate electrode;
a pair of source/drain regions, oppositely disposed in the silicon substrate adjacent the gate stack; and
a metallized bilayer overlying each source/drain reigon and the silicon gate electrode to thereby respectively reduce resistance thereof, wherein the metallized bilayer comprises a metal top layer.

7. The transistor as claimed in claim 6, further comprising a metal silicide layer disposed between the metal top layer and each source/drain region and the silicon gate electrode.

8. The transistor as claimed in claim 6, wherein the metal top layer comprises the same type of metal ion as that of the metal silicide layer.

9. The transistor as claimed in claim 6, wherein the metal top layer comprises refractory metal.

10. The transistor as claimed in claim 6, wherein the metal silicide layer comprises a silicide of refractory metal.

11. The transistor as claimed in claim 6, wherein the metal top layer comprises metal selected from a group consisting of Au, Pt, Ni, Co, Pd, W and Ti.

12. A method of fabricating a semiconductor device, comprising the steps of:
providing a semiconductor device body exposing at least one silicon-containing portion;
selectively forming a metal silicide layer with a first resistivity over the silicon-containing portion; and
forming a conductor layer with a second resistivity on the metal silicide layer, wherein the second resistivity is smaller than the first resistivity.

13. The method as claimed in claim 12, wherein the conductor layer comprises the same type of metal ion as that of the metal silicide layer.

14. The method as claimed in claim 12, wherein the metal layer comprises refractory metal.

15. The method as claimed in claim 12, wherein the conductor silicide layer comprises a silicide of refractory metal.

16. The method as claimed in claim 12, wherein the metal layer comprises a metal selected from a group consisting of Au, Pt, Ni, Co, Pd, W and Ti.

17. The method as claimed in claim 12, wherein the conductor layer is formed by electroless plating.

18. The method as claimed in claim 17, wherein the electroless plating is performed in an electrolyte comprising at least a reducing agent, a catalyst, a complex agent and metal ions of the metal layer.

19. The method as claimed in claim 18, wherein the catalyst comprises Pd or metal ions of the conductor layer.

20. The method as claimed in claim 12, wherein a thickness ratio between the metal silicide layer and the conductor layer is about 1:1 to 1:10.

21. A method of fabricating a resistance-reduced transistor, comprising the steps of:
providing a silicon substrate having a gate stack formed thereon and a source/drain pair oppositely formed in each side of the substrate adjacent to the gate stack, wherein the gate stack comprises an exposed silicon gate electrode;
selectively forming a metal silicide layer over the source/drain regions and the exposed silicon gate electrode; and
selectively forming a metal layer over each metal silicide layer by electroless plating to respectively reduce resistance of each source/drain region and the exposed silicon gate electrode.

22. The method as claimed in claim 21, wherein the metal layer comprises the same type of metal ion as that of the metal silicide layer.

23. The method as claimed in claim 21, wherein the metal layer comprises refractory metal.

24. The method as claimed in claim 21, wherein the metal silicide layer comprises a silicide of refractory metal.

25. The method as claimed in claim 21, wherein the metal layer comprises a metal selected from a group consisting of Au, Pt. Ni, Co, Pd, W and Ti.

26. The method as claimed in claim 21, wherein the electroless plating is performed in an electrolyte comprising at least a reducing agent, a catalyst, a complex agent and metal ions of the metal layer.

27. The method as claimed in claim 26, wherein the catalyst comprises Pd or the metal ions of the metal layer.

28. The method as claimed in claim 21, wherein a thickness ratio between the metal silicide layer and the metal layer is about 1:1 to 1:10.
